(19) United States
(12) Patent Application Publication
(10) Pub. No.: US 2025/0008720 A1
(43) Pub. Date: Jan. 2, 2025

(54) SEMICONDUCTOR STORAGE CELL STRUCTURE AND MANUFACTURING METHOD THEREOF

(71) Applicant: Taiwan Semiconductor Manufacturing Company, Ltd., Hsinchu (TW)

(72) Inventor: Chia-Yu LING, Hsinchu (TW)

(73) Assignee: Taiwan Semiconductor Manufacturing Company, Ltd., Hsinchu (TW)

(21) Appl. No.: 18/215,600

(22) Filed: Jun. 28, 2023

(51) Int. Cl. H10B 12/00

(52) U.S. Cl. CPC H10B 12/00

(57) ABSTRACT

A semiconductor storage cell structure and a manufacturing method thereof are provided. The manufacturing method of the semiconductor storage cell structure includes the following steps. A first transistor, which is a gate-all-around (GAA) structure, is formed. A second transistor is formed on the first transistor. An assistance gate layer is disposed above a storage node.

### BACKGROUND

The disclosure relates in general to a semiconductor structure and a manufacturing method thereof, and more particularly to a semiconductor storage cell structure and a manufacturing method thereof.

Currently, a common storage cell structure is composed of a transistor and a capacitor connected to a drain of the transistor. This structure needs to constantly refresh the charge in the capacitor to ensure that the data is not lost, and the charge in the capacitor needs to be released when reading, and then rewritten after reading, which consumes a lot of power. Moreover, because the capacitor occupies a large area, it is difficult to shrink the size.

With the miniaturization of device size, the traditional storage cell structure is facing huge challenges in terms of storage density, power consumption, and performance. The reduction of the capacitance and the increase of the off-state leakage current lead to shorten the data retention time and increased power consumption.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a circuit diagram of a semiconductor storage cell structure according to one embodiment.

FIG. 2 shows a stereo view of the semiconductor storage cell structure.

FIG. 3 shows a section view of the semiconductor storage cell structure.

FIGS. 4A to 4F illustrate a manufacturing method of the semiconductor storage cell structure according to one embodiment.

FIG. 5 shows a top view of the semiconductor storage cell structure according to one embodiment.

FIG. 6 shows a stereo view of a plurality of semiconductor storage cell structures according to one embodiment.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

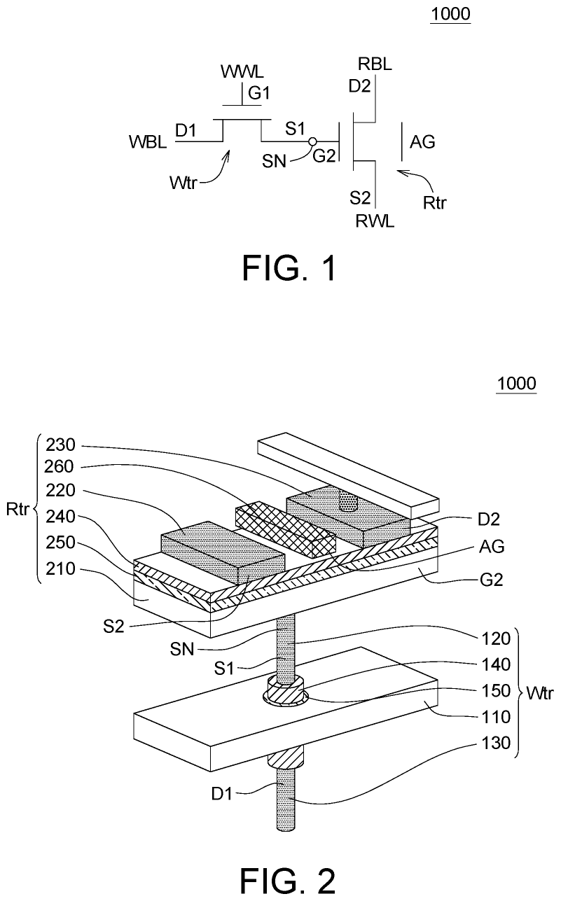

Please refer to FIG. 1, which shows a circuit diagram of a semiconductor storage cell structure 1000 according to one embodiment. The semiconductor storage cell structure 1000 includes a first transistor Wtr and a second transistor Rtr. A drain D1 of the first transistor Wtr is connected to a first bit line WBL. A gate G1 of the first transistor Wtr is connected to a first word line WWL. A source S1 of the first transistor Wtr is connected to a gate G2 of the second transistor Rtr. A drain D2 of the second transistor Rtr is connected to a second bit line RBL. A source S2 of the second transistor Rtr is connected to a second word line RWL. A storage node SN is formed at the connection of the source S1 of the first transistor Wtr and the gate G2 of the second transistor Rtr.

The semiconductor storage cell structure 1000 is an implementation of DRAM with 2T0C (two transistors and zero capacitor). In the semiconductor storage cell structure 1000, the first transistor Wtr is a write transistor, and the second transistor Rtr is a read transistor. The source S1 of the write transistor, i.e. the first transistor Wtr, is connected to the gate G2 of the read transistor, i.e. the second transistor Rtr. The charge in the gate capacitance of the second transistor Rtr, i.e. the storage node SN is changed through the first transistor Wtr, thereby affecting the resistance state between the source S2 and the drain D2 of the second transistor Rtr, and realizing the distinction between “0” and “1”. The specific principle of this operation is described as follows.

In the operation of writing “1”, a positive voltage, which greater than the threshold voltage of the first transistor Wtr, is applied to the gate G1 of the first transistor Wtr via the first word line WWL to make the first transistor Wtr being opened, and a positive voltage is applied to the source S1 of the first transistor Wtr via the first bit line WBL. A positive voltage injects charges into the gate capacitance of the second transistor Rtr, i.e. the storage node SN. After the charges are injected, the voltages applied on the gate G1 and the source S1 of the first transistor Wtr are removed, and the “1” state is saved.

In the operation of reading “1”, a reading voltage is applied to the drain D2 of the second transistor Rtr. Since there is a certain charges in the gate capacitance, the second transistor Rtr is at a lower resistance state, and a large current passes through the second read word line RWL, and then this large current is amplified by a peripheral circuit and then identified to complete the operation of reading “1”.

In the operation of writing “0”, a positive voltage which is greater than the threshold voltage of the first transistor Wtr is applied to the gate G1 of the first transistor Wtr via the first word line WWL to make the first transistor Wtr being opened, and a negative voltage or a zero voltage is applied to the source S1 of the first transistor Wtr via the first bit line WBL. The negative voltage or the zero voltage extracts the charges from the gate capacitance of the second transistor Rtr, i.e. the storage node SN. After the charges are extracted, the voltage applied on the gate G1 and the source S1 of the first transistor Wtr are removed, and the “0” state is saved.

In the operation of reading “0”, the reading voltage is applied to the drain D2 of the second transistor Rtr. Since there is no charge (or few charges) in the gate capacitance of the second transistor Rtr, the second transistor Rtr is at a high resistance state, and a small current passes through the second read word line RWL, and then this small current is amplified and identified to complete the operation of reading “0.”

As described above, “0” or “1” is stored by the charges kept in the gate capacitance of the second transistor Rtr, i.e. the storage node SN. Referring to FIG. 1, an assistance gate AG is used as a second gate of the second transistor Rtr. The assistance gate AG can apply negative bias for lower channel leakage to extend data retention.

Please refer to FIG. 2, which shows a stereo view of the semiconductor storage cell structure 1000. The first transistor Wtr is a gate-all-around (GAA) structure, and the second transistor Rtr is disposed on the first transistor Wtr. The first transistor Wtr and the second transistor Rtr are stacked in vertical, so that the occupied area of one storage cell can be reduced and the storage density can be increased.

The first transistor Wtr includes a first gate layer 110, a first source layer 120, a first drain layer 130, a first channel layer 140 and a first gate dielectric layer 150. The first gate dielectric layer 150 surrounds the first channel layer 140. The first gate layer 110 surrounds the first gate dielectric layer 150 to form the gate G1 of the first transistor Wtr. The first source layer 120 is disposed at one side of the first channel layer 140 to form the source S1 of the first transistor Wtr. The first drain layer 130 is disposed at another side of the first channel layer 140 to form the drain D1 of the first transistor Wtr.

The first gate layer 110, the first source layer 120 and the first drain layer 130 are used as electrodes to be connected to the power supply or another component. The material of the first gate layer 110, the first source layer 120 and/or the first drain layer 130 is, for example, a metal material with good electrical conductivity, such as Mo (Molybdenum), Ti (Titanium), W (Tungsten), Cu (Copper), TiN (Titanium nitride), Al (aluminum), Ru (Ruthenium), Ag (Silver), Au (Gold), In—Ti—O (ITO, indium tin oxide) or a combination thereof.

The first gate dielectric layer 150 provides insulating between the first gate layer 110 and the first channel layer 140 of the first transistor Wtr. The material of the first gate dielectric layer 150 is, for example, selected from a material with a wide band gap and a high dielectric constant, or a material suitable for making extremely small-sized devices, such as HfO₂ (Hafnium oxide), Al₂O₃ (Aluminium oxide), La₂O₃ (Lanthanum oxide), ZrO (Zirconium dioxide) or the combination thereof.

The first channel layer 140 is, for example, pillar shaped. In some embodiments, the first channel layer 140 continuously extends between the first source layer 120 and the first drain layer 130, and the first channel layer 140 continuously penetrates through the first gate dielectric layer 150 and the first gate layer 110. The material of the first channel layer 140 is, for example, Si (silicon), poly-Si (p-Si, polycrystalline silicon), amorphous-Si (a-Si, amorphous silicon), In—Ga—Zn—O (IGZO, indium gallium zinc oxide) multiple compounds, ZnO (zinc oxide), In—Ti—O (ITO, indium tin oxide), TiO₂ (titanium dioxide), MoS₂ (molybdenum disulfide), WS₂ (tungsten disulfide) or a combination thereof.

The second transistor Rtr includes a second gate layer 210, a second source layer 220, a second drain layer 230, a second channel layer 240, a second gate dielectric layer 250 and the assistance gate layer 260. The second gate layer 210 is used to form the gate of the second transistor Rtr. The second gate layer 210 is connected to the first source layer 120. The second gate dielectric layer 250 is disposed on the second gate layer 210. The second channel layer 240 is disposed on the second gate dielectric layer 250. The second source layer 220 is disposed on the second channel layer 240 to form the source S2 of the second transistor Rtr. The second drain layer 230 is disposed on the second channel layer 240 and separated with the second source layer 220 to form the drain D2 of the second transistor Rtr. The assistance gate layer 260 is disposed above the second channel layer 240 and located between the second source layer 220 and the second drain layer 230 to form the assistance gate AG. The storage node SN is formed at the connection of the source S1 of the first transistor Wtr and the gate G2 of the second transistor Rtr.

The second gate layer 210, the second source layer 220, the second drain layer 230 and the assistance gate layer 260 are used as electrodes to be connected to the power supply or another component. The material of second gate layer 210, the second source layer 220, the second drain layer 230 and/or the assistance gate layer 260 is, for example, a metal material with good electrical conductivity, such as Mo (Molybdenum), Ti (Titanium), W (Tungsten), Cu (Copper), TiN (Titanium nitride), Al (aluminum), Ru (Ruthenium), Ag (Silver), Au (Gold), In—Ti—O (ITO, indium tin oxide) or a combination thereof.

The second gate dielectric layer 250 provides insulating between the second gate layer 210 and the second channel layer 240 of the second transistor Rtr. The material of the second gate dielectric layer 250 is, for example, selected from a material with a wide band gap and a high dielectric constant, or a material suitable for making extremely small-sized devices, such as HfO₂ (Hafnium oxide), Al₂O₃ (Aluminium oxide), La₂O₃ (Lanthanum oxide), ZrO (Zirconium dioxide) or the combination thereof.

The first channel layer 140 and the second channel 240 are overlapped. The material of the second channel layer 240 is, for example, Si (silicon), poly-Si (p-Si, polycrystalline silicon), amorphous-Si (a-Si, amorphous silicon), In—Ga—Zn—O (IGZO, indium gallium zinc oxide) multiple compounds, ZnO (zinc oxide), In—Ti—O (ITO, indium tin oxide), TiO₂ (titanium dioxide), MoS₂ (molybdenum disulfide), WS₂ (tungsten disulfide) or a combination thereof.

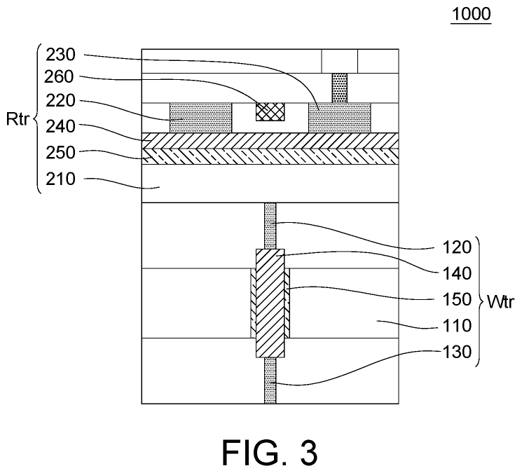

Please refer to FIG. 3, which shows a section view of the semiconductor storage cell structure 1000. The second transistor Rtr is disposed on the first transistor Wtr. The first transistor Wtr and the second transistor Rtr are stacked in vertical. The first transistor Wtr and the second transistor Rtr are formed at different times. For example, the first transistor Wtr is formed first, then the second transistor Rtr is formed on the first transistor Wtr.

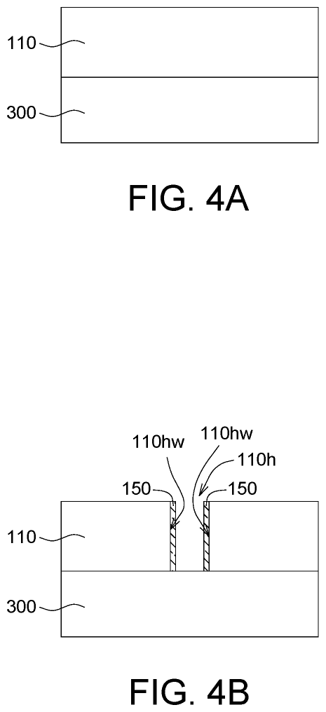

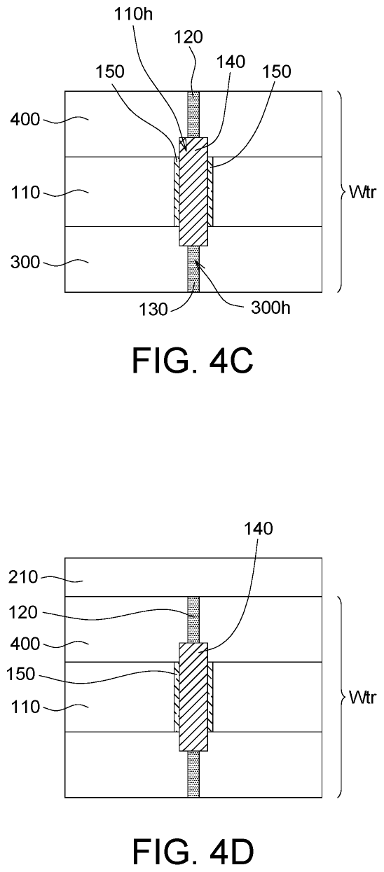

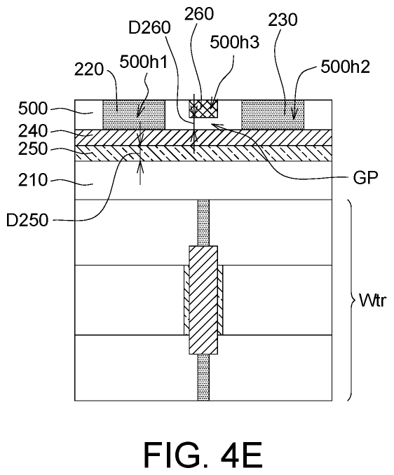

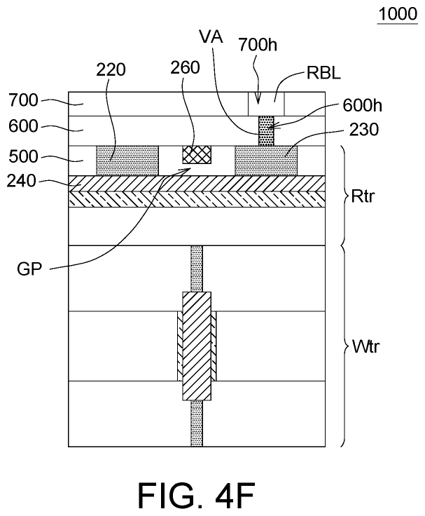

Please refer to FIGS. 4A to 4F, which illustrate a manufacturing method of the semiconductor storage cell structure 1000 according to one embodiment. As sown in FIG. 4A, the first gate layer 110 is formed on a base 300. The base 300 is, for example, a substrate or an interlayer dielectric. For example, the first gate layer 110 may be formed by deposing Mo (Molybdenum), Ti (Titanium), W (Tungsten), Cu (Copper), TiN (Titanium nitride), Al (aluminum), Ru (Ruthenium), Ag (Silver), Au (Gold), In—Ti—O (ITO, indium tin oxide) or a combination thereof via an Atomic Layer Deposition (ALD) process, a Chemical Vapor Deposition (CVD) process or a Physical vapor deposition (PVD) process.

Then, as shown in FIG. 4B, a through hole 110h passing through the first gate layer 110 is formed. For example, the through hole 110h may be formed via a photolithography process and an etching (dry etching or wet etching) process.

Next, as shown in FIG. 4B, the first gate dielectric layer 150 is formed at a side wall 110hw of the through hole 110h. As shown in FIG. 2, the first gate dielectric layer 150 is surrounded by the first gate layer 110. For example, the first gate dielectric layer 150 may be formed via disposing HfO₂ (Hafnium oxide), Al₂O₃ (Aluminium oxide), La₂O₃ (Lanthanum oxide), ZrO (Zirconium dioxide) or the combination thereof via the Atomic Layer Deposition (ALD) process, the Chemical Vapor Deposition (CVD) process or the Physical vapor deposition (PVD) process, and then etching the deposition material.

Afterwards, as shown in FIG. 4C, the base 300 is etched to form a concave 300h. For example, the concave 300h may be formed via the photolithography process and the etching (dry etching or wet etching) process. In one embodiment, the concave 300h may be formed when etching the deposition material to form the first gate dielectric layer 150. The concave 300h in the base 300 has a lower portion filled with 130 and an upper portion filled with 140, and the upper portion has a size larger than the lower portion. The concave 300 is, for example, formed by dual damascene, or the concave 300 is firstly formed to have a smaller size and then the upper portion thereof is expanded to have a larger size.

Next, as shown in FIG. 4C, the first drain layer 130 is formed in the concave 300h. For example, the first drain layer 130 may be formed by deposing Mo (Molybdenum), Ti (Titanium), W (Tungsten), Cu (Copper), TiN (Titanium nitride), Al (aluminum), Ru (Ruthenium), Ag (Silver), Au (Gold), In—Ti—O (ITO, indium tin oxide) or the combination thereof via the Atomic Layer Deposition (ALD) process, the Chemical Vapor Deposition (CVD) process or the Physical vapor deposition (PVD) process.

Afterwards, as shown in FIG. 4C, the first channel layer 140 is formed in the through hole 110h. One side of the first channel layer 140 is connected to the first drain layer 130. As shown in FIG. 2, the first channel layer 140 is surrounded by the first gate dielectric layer 150. The through hole 110h is fully filled by the first channel layer 140 and the first gate dielectric layer 150. For example, the first channel layer 140 may be formed by deposing Si (silicon), poly-Si (p-Si, polycrystalline silicon), amorphous-Si (a-Si, amorphous silicon), In—Ga—Zn—O (IGZO, indium gallium zinc oxide) multiple compounds, ZnO (zinc oxide), In—Ti—O (ITO, indium tin oxide), TiO2 (titanium dioxide), MoS2 (molybdenum disulfide), WS2 (tungsten disulfide) or the combination thereof via the Atomic Layer Deposition (ALD) process, the Chemical Vapor Deposition (CVD) process or the Physical vapor deposition (PVD) process.

Next, as shown in FIG. 4C, the first source layer 120 is formed on the first channel layer 140. The first source layer 120 is connected to the first channel layer 140. For example, the first source layer 120 may be formed by deposing Mo (Molybdenum), Ti (Titanium), W (Tungsten), Cu (Copper), TiN (Titanium nitride), Al (aluminum), Ru (Ruthenium), Ag (Silver), Au (Gold), In—Ti—O (ITO, indium tin oxide) or the combination thereof via the Atomic Layer Deposition (ALD) process, the Chemical Vapor Deposition (CVD) process or the Physical vapor deposition (PVD) process and then etching the deposition material.

Afterwards, as shown in FIG. 4D, an insulating layer 400 is formed to cover the first gate layer 110, the first channel layer 140 and the first gate dielectric layer 150, and expose the first source layer 120. The side wall of the first source layer 120 is covered by the insulating layer 400. For example, the insulating layer 400 may be formed by deposing silicon oxide via the Atomic Layer Deposition (ALD) process, the Chemical Vapor Deposition (CVD) process or the Physical vapor deposition (PVD) process and then etching the deposition material.

As shown in FIG. 4D, the first transistor Wtr which is a gate-all-around (GAA) structure is formed.

Next, as shown in FIG. 4E, the second gate layer 210 is formed on the insulating layer 400 and the first source layer 120. The second gate layer 210 is connected to the first source layer 120. For example, the second gate layer 210 may be formed by deposing Mo (Molybdenum), Ti (Titanium), W (Tungsten), Cu (Copper), TiN (Titanium nitride), Al (aluminum), Ru (Ruthenium), Ag (Silver), Au (Gold), In—Ti—O (ITO, indium tin oxide) or a combination thereof via an Atomic Layer Deposition (ALD) process, a Chemical Vapor Deposition (CVD) process or a Physical vapor deposition (PVD) process.

Then, as shown in FIG. 4E, the second gate dielectric layer 250 is formed on the second gate layer 210. For example, the second gate dielectric layer 250 may be formed via disposing HfO2 (Hafnium oxide), Al2O3 (Aluminium oxide), La2O3 (Lanthanum oxide), ZrO (Zirconium dioxide) or the combination thereof via the Atomic Layer Deposition (ALD) process, the Chemical Vapor Deposition (CVD) process or the Physical vapor deposition (PVD) process, and then etching the deposition material.

Afterwards, as shown in FIG. 4E, the second channel layer 240 is formed on the second gate dielectric layer 250. For example, the second channel layer 240 may be formed by deposing Si (silicon), poly-Si (p-Si, polycrystalline silicon), amorphous-Si (a-Si, amorphous silicon), In—Ga—Zn—O (IGZO, indium gallium zinc oxide) multiple compounds, ZnO (zinc oxide), In—Ti—O (ITO, indium tin oxide), TiO2 (titanium dioxide), MoS2 (molybdenum disulfide), WS2 (tungsten disulfide) or the combination thereof via the Atomic Layer Deposition (ALD) process, the Chemical Vapor Deposition (CVD) process or the Physical vapor deposition (PVD) process.

Next, as shown in FIG. 4E, an insulating layer 500 is formed on the second channel layer 240. For example, the insulating layer 500 may be formed by deposing silicon oxide via the Atomic Layer Deposition (ALD) process, the Chemical Vapor Deposition (CVD) process or the Physical vapor deposition (PVD) process and then etching the deposition material.

Afterwards, as shown in FIG. 4E, the insulating layer 500 is etched to form tow concaves 500h1, 500h2 exposing part of the second channel layer 240. The concave 500h1 is separated with the concave 500h2. For example, the concaves 500h1, 500h2 may be formed via the photolithography process and the etching (dry etching or wet etching) process.

Next, as shown in FIG. 4E, the second source layer 220 and the second drain layer 230 are formed in the concaves 500h1, 500h2 and on the second channel layer 240. The second drain layer 230 is separated with the second source layer 220. For example, the second source layer 220 and the second drain layer 230 may be formed by deposing Mo (Molybdenum), Ti (Titanium), W (Tungsten), Cu (Copper), TiN (Titanium nitride), Al (aluminum), Ru (Ruthenium), Ag (Silver), Au (Gold), In—Ti—O (ITO, indium tin oxide) or the combination thereof via the Atomic Layer Deposition (ALD) process, the Chemical Vapor Deposition (CVD) process or the Physical vapor deposition (PVD) process.

Then, as shown in FIG. 4E, the insulating layer 500 is etched to form a concave 500h3. The concave 500h3 does not expose the second channel layer 240. There is a gap GP between the bottom of the concave 500h3 and the top of the second channel layer 240. For example, the concave 500h3 may be formed via the photolithography process and the etching (dry etching or wet etching) process.

Next, as shown in FIG. 4E, the assistance gate layer 260 is formed in the concave 500h3. The assistance gate layer 260 is located above the second channel layer 240 and located between the second source layer 220 and the second drain layer 230. As shown in FIG. 4E, the assistance gate layer 260 and the second channel layer 140 are separated by the gap GP. The assistance gate layer 260 and the second channel layer 240 are formed at two separated spaces. A distance D260 between the assistance gate layer 260 and the second channel layer 240 is equal to or less than a thickness D250 of the second gate dielectric layer 250. The assistance gate layer 260 is formed above the second channel layer 240 with a space whose height is equal to or less than the thickness D250 of the second gate dielectric layer 250. For example, the assistance gate layer 260 may be formed by deposing Mo (Molybdenum), Ti (Titanium), W (Tungsten), Cu (Copper), TiN (Titanium nitride), Al (aluminum), Ru (Ruthenium), Ag (Silver), Au (Gold), In—Ti—O (ITO, indium tin oxide) or a combination thereof via an Atomic Layer Deposition (ALD) process, a Chemical Vapor Deposition (CVD) process or a Physical vapor deposition (PVD) process.

Then, as shown in FIG. 4F, an insulating layer 600 is formed on the insulating layer 500, the second source layer 220, the assistance gate layer 260 and the second drain layer 230. For example, the insulating layer 600 may be formed by deposing silicon oxide via the Atomic Layer Deposition (ALD) process, the Chemical Vapor Deposition (CVD) process or the Physical vapor deposition (PVD) process and then etching the deposition material.

Next, as shown in FIG. 4F, the insulating layer 600 is etched to form a concave 600h. For example, the concave 600h may be formed via the photolithography process and the etching (dry etching or wet etching) process.

Then, as shown in FIG. 4F, a via VA is formed in the concave 600h. For example, the via VA may be formed by deposing Mo (Molybdenum), Ti (Titanium), W (Tungsten), Cu (Copper), TiN (Titanium nitride), Al (aluminum), Ru (Ruthenium), Ag (Silver), Au (Gold), In—Ti—O (ITO, indium tin oxide) or a combination thereof via an Atomic Layer Deposition (ALD) process, a Chemical Vapor Deposition (CVD) process or a Physical vapor deposition (PVD) process.

Next, as shown in FIG. 4F, an insulating layer 700 is formed on the insulating layer 600 and the via VA. For example, the insulating layer 700 may be formed by deposing silicon oxide via the Atomic Layer Deposition (ALD) process, the Chemical Vapor Deposition (CVD) process or the Physical vapor deposition (PVD) process and then etching the deposition material.

Afterward, as shown in FIG. 4F, the insulating layer 700 is etched to form a concave 700h. For example, the concave 700h may be formed via the photolithography process and the etching (dry etching or wet etching) process.

Next, as shown in FIG. 4F, the second bit line RBL is formed in the concave 700h. For example, the second bit line RBL may be formed by deposing Mo (Molybdenum), Ti (Titanium), W (Tungsten), Cu (Copper), TiN (Titanium nitride), Al (aluminum), Ru (Ruthenium), Ag (Silver), Au (Gold), In—Ti—O (ITO, indium tin oxide) or a combination thereof via an Atomic Layer Deposition (ALD) process, a Chemical Vapor Deposition (CVD) process or a Physical vapor deposition (PVD) process.

As shown in FIG. 4F, the second transistor Rtr is formed on the first transistor Wtr which is the GAA structure and the semiconductor storage cell structure 1000 is formed.

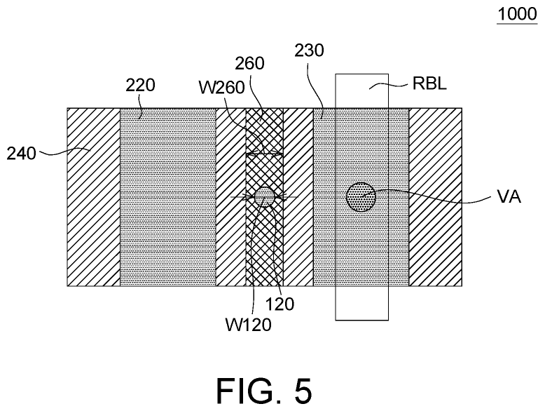

FIG. 5, which shows a top view of the semiconductor storage cell structure 1000 according to one embodiment.

Please refer to FIG. 5, which shows a top view of the semiconductor storage cell structure 1000 according to one embodiment. The assistance gate layer 260 is located between the second source 220 and the second drain source 230. The assistance gate layer 260 is formed at a region overlapping with the first source layer 120. As shown in FIG. 5, a width W260 of the assistance gate layer 260 is larger than a width W 120 of the first source layer 120.

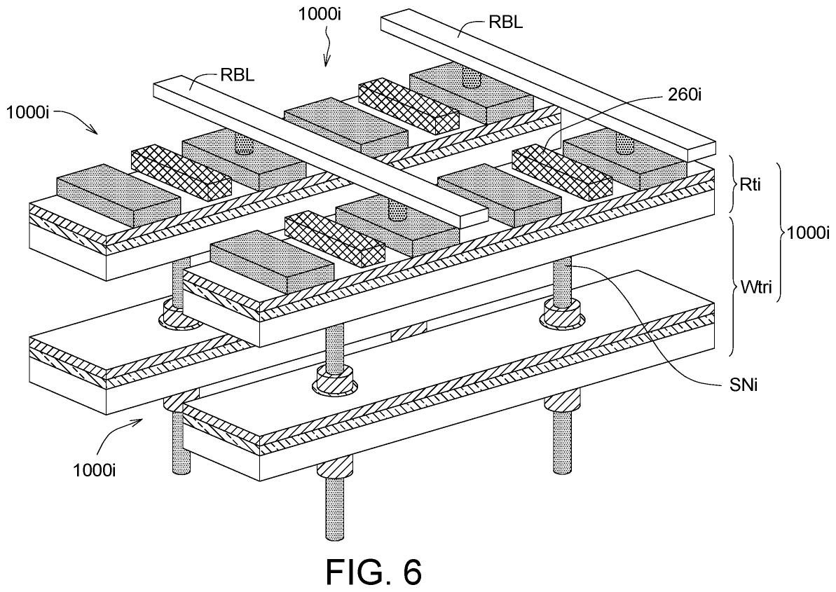

Please refer to FIG. 6, which shows a stereo view of a plurality of semiconductor storage cell structures 1000i according to one embodiment. The semiconductor storage cell structures 1000i are connected and arranged in array structure. Because the first transistors Wtri and the second transistors Rtri are disposed in vertical direction, the size could be greatly shrunk, so that the storage density could be increased.

Furthermore, the assistance gate layer 260i in each of the second transistors Rtri is disposed above the storage node SNi. Therefore, the data retention time and the power consumption could be improved.

According to one embodiment, a semiconductor storage cell structure is provided. The semiconductor storage cell structure includes a first transistor and a second transistor. The first transistor is a gate-all-around (GAA) structure. The second transistor is disposed on the first transistor. An assistance gate layer is disposed above a storage node.

According to another embodiment, a manufacturing method of a semiconductor storage cell structure is provided. The manufacturing method of the semiconductor storage cell structure includes the following steps. A first transistor, which is a gate-all-around (GAA) structure, is formed. A second transistor is formed on the first transistor. An assistance gate layer is disposed above a storage node.

According to an alternative embodiment, a semiconductor storage cell structure is provided. The semiconductor storage cell structure includes a first transistor and a second transistor. The second transistor is disposed on the first transistor. The first transistor has a vertical channel, and the second transistor has a horizontal channel.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor storage cell structure, comprising:
a first transistor, which is a gate-all-around (GAA) structure; and
a second transistor, disposed on the first transistor;
wherein an assistance gate layer is disposed above a storage node.

2. The semiconductor storage cell structure according to claim 1, wherein the first transistor includes:
a first channel layer;
a first gate dielectric layer, surrounding the first channel layer;
a first gate layer, surrounding the first gate dielectric layer;
a first source layer, disposed at one side of the first channel layer; and
a first drain layer, disposed at another side of the first channel layer.

3. The semiconductor storage cell structure according to claim 2, wherein the second transistor includes:
a second gate layer, connected to the first source layer;
a second gate dielectric layer, disposed on the second gate layer;
a second channel layer, disposed on the second gate dielectric layer;
a second source layer, disposed on the second channel layer;
a second drain layer, disposed on the second channel layer, and separated with the second source layer; and
the assistance gate layer, disposed above the second channel layer and located between the second source layer and the second drain layer.

4. The semiconductor storage cell structure according to claim 3, wherein the assistance gate layer overlaps with the first source layer.

5. The semiconductor storage cell structure according to claim 3, wherein a width of the assistance gate layer is larger than a width of the first source layer.

6. The semiconductor storage cell structure according to claim 3, wherein the assistance gate layer and the second channel layer are separated by a gap.

7. The semiconductor storage cell structure according to claim 3, wherein a distance between the assistance gate layer and the second channel layer is equal to or less than a thickness of the second gate dielectric layer.

8. The semiconductor storage cell structure according to claim 3, wherein a material of the assistance gate layer is Mo, Ti, W, Cu, TiN, Al, Ru, Ag, Au, In—Ti—O (ITO) or a combination thereof.

9. A manufacturing method of a semiconductor storage cell structure, comprising:
forming a first transistor, which is a gate-all-around (GAA) structure; and
forming a second transistor on the first transistor, wherein an assistance gate layer is disposed above a storage node.

10. The manufacturing method of the semiconductor storage cell structure according to claim 9, wherein the step of forming the first transistor includes:
forming a first gate layer on a base;
forming a through hole passing through the first gate layer;
forming a first gate dielectric layer at a side wall of the through hole, wherein the first gate dielectric layer is surrounded by the first gate layer;
etching the base to form a concave;
forming a first drain layer in the concave;
forming a first channel layer in the through hole, wherein one side of the first channel layer is connected to the first drain layer, the first channel layer is surrounded by the first gate dielectric layer;
forming a first source layer connected to the first channel layer; and
forming an insulating layer covering the first gate layer and the first gate dielectric layer and exposing the first source layer.

11. The manufacturing method of the semiconductor storage cell structure according to claim 10, wherein the step of forming the second transistor includes:
forming a second gate layer connected to the first source layer;
forming a second gate dielectric layer on the second gate layer;
forming a second channel layer on the second gate dielectric layer;
forming a second source layer and a second drain layer on the second channel layer, wherein the second drain layer is separated with the second source layer; and
forming the assistance gate layer above the second channel layer and located between the second source layer and the second drain layer.

12. The manufacturing method of the semiconductor storage cell structure according to claim 11, wherein the assistance gate layer is formed at a region overlapping with the first source layer.

13. The manufacturing method of the semiconductor storage cell structure according to claim 11, wherein the assistance gate layer is formed at a region whose width is larger than a width of the first source layer.

14. The manufacturing method of the semiconductor storage cell structure according to claim 11, wherein the assistance gate layer and the second channel layer are formed at two separated spaces.

15. The manufacturing method of the semiconductor storage cell structure according to claim 11, wherein the assistance gate layer is formed above the second channel layer with a space whose height is equal to or less than a thickness of the second gate dielectric layer.

16. A semiconductor storage cell structure, comprising:
a first transistor; and
a second transistor, disposed on the first transistor;
wherein the first transistor has a vertical channel, and the second transistor has a horizontal channel.

17. The semiconductor storage cell structure according to claim 16, wherein the first transistor includes:
a first channel layer, extended along a first direction;
a first gate dielectric layer, surrounding the first channel layer;
a first gate layer, surrounding the first gate dielectric layer;
a first source layer, disposed at one side of the first channel layer; and
a first drain layer, disposed at another side of the first channel layer.

18. The semiconductor storage cell structure according to claim 17, wherein the second transistor includes:
a second gate layer, connected to the first source layer;
a second gate dielectric layer, disposed on the second gate layer;
a second channel layer, disposed on the second gate dielectric layer and extended along a second direction which is substantially perpendicular to the first direction;
a second source layer, disposed on the second channel layer;
a second drain layer, disposed on the second channel layer, and separated with the second source layer; and
an assistance gate layer, disposed above the second channel layer and located between the second source layer and the second drain layer.

19. The semiconductor storage cell structure according to claim 18, wherein the first channel layer is pillar shaped.

20. The semiconductor storage cell structure according to claim 18, wherein the first channel layer and the second channel layer are overlapped.
